(19) United States
(12) Patent Application Publication
(10) Pub. No.: US 2009/0280431 A1
(43) Pub. Date: Nov. 12, 2009

(54) MATERIAL FOR PROTECTIVE FILM FORMATION, AND METHOD FOR PHOTORESIST PATTERN FORMATION USING THE SAME

(75) Inventors: Tomoyuki Hirano, Kawasaki-shi (JP); Kotaro Endo, Kawasaki-shi (JP); Keita Ishiduka, Kawasaki-shi (JP)

Correspondence Address: PROCOPIO, CORY, HARGREAVES & SAVITCH LLP, 530 B STREET, SUITE 2100, SAN DIEGO, CA, 92101, US

(73) Assignee: TOKYO OHKA KOGYO CO., LTD., Kawasaki-shi, Kanagawa (JP)

(21) Appl. No.: 12/066,127

(22) PCT Filed: Sep. 8, 2006
(86) PCT No.: PCT/JP2006/317879

§ 371 Date: Mar. 7, 2008

(30) Foreign Application Priority Data
Sep. 9, 2005 (JP) 2005-263065
Sep. 8, 2006 (JP) PCT/JP2006/317879

(51) Int. Cl. G03F 7/20; G03F 7/004

(52) U.S. Cl. 430/270.1; 430/325

(57) ABSTRACT

To provide a material for protective film formation that can simultaneously prevent a change in quality of a resist film during liquid immersion exposure and a change in quality of a liquid for liquid immersion exposure used, and, at the same time, can form a resist pattern having a good shape without increasing the number of treatment steps. A material for protective film formation, comprising at least an alkali-soluble polymer comprising constitutional units represented by general formula (1):

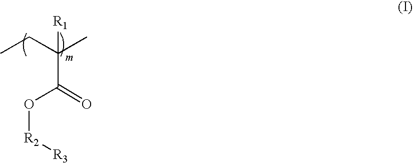

wherein R₁ represents a hydrogen atom or a methyl group; R₂ represents an alkylene chain having 1 to 5 carbon atoms; R₃ represents a fluorinated alkylene chain having 1 to 10 carbon atoms in which a part or all of hydrogen atoms have been substituted by a fluorine atom; and m is a repeating unit.

### TECHNICAL FIELD

The present invention relates to a material for forming a resist protective film, and a method for forming a photoresist pattern using the same. Particularly, the present invention relates to a material for forming a resist protective film which is suitable for a liquid immersion lithography process, in which the resist film is exposed while being interposed by a liquid having a predetermined thickness and refractive index which is larger than that of an air and smaller than that of the resist film, on at least the resist film on a route of allowing lithographic exposure light to reach to the resist film, and relates to a method for forming a photoresist pattern using the material.

### BACKGROUND ART

Conventionally, lithography methods have been frequently used for the production of fine structures in various kinds of electronic devices such as semiconductor devices and liquid crystal devices. However, as the device structures are miniaturized, resist patterns in lithography processes are also desired to be miniaturized.

In the advanced field, for example, a lithography process now allows the formation of a fine resist pattern having a line width of about 90 nm. However, finer pattern formation will be required in future.

For attaining the formation of such a fine pattern having a line width of less than 90 nm, a first step is to develop a lithography device and a corresponding resist. Common factors to consider for developing the lithography device include shortening of wavelengths of light sources such as F₂ excimer laser, EUV (extreme UV light), electron beam, X-ray, soft X-ray and the like, and increases in numerical aperture (NA) of lens.

However, the shortening of the optical wavelength may require a new and more expensive lithography device. In addition, due to an inverse relationship between the resolution and the focal depth width, even if the resolution is increased, a disadvantage occurs at high NA in which focal depth width decreases.

Recently, as a lithography technology for allowing such problems to be solved, a method known as a liquid immersion lithography process has been reported (e.g., Non-Patent Documents 1, 2, and 3). In this process, a liquid for liquid immersion lithography such as pure water or a fluorine-based inert liquid is interposed in a predetermined thickness on at least a resist film between a lens and the resist film during the exposure. In this method, the space of the path of exposure light, which is conventionally filled with an inert gas such as air or nitrogen, is replaced with a liquid having a higher refractive index (n), for example pure water, to attain high resolution without a decrease in focal depth width, similarly to the use of a light source of shorter wavelength or a high NA lens, even if a light source having the same exposure wavelength is employed.

Such liquid immersion lithography has been given considerable attention because its use allows a lens implemented in the existing device to realize the formation of a resist pattern superior in higher resolution property as well as excellent in focal depth in low costs.

However, in such a liquid immersion lithography process, a liquid for liquid immersion lithography such as pure water or a fluorine-based inert liquid is interposed on the top layer of the resist film, so that there is a naturally concern such as the deterioration of the resist film caused by the liquid for liquid immersion lithography during the liquid immersion lithography, and the variation of the refractive index accompanied by the deterioration of the liquid itself due to eluted components from the resist film.

Although the materials used in a conventional lithography process may be utilized without any adjustment in such a liquid immersion lithography process, it has been proposed to use a material different from those of the conventional lithography process under different exposure conditions in which the liquid for liquid immersion lithography is interposed between a lens and a resist film.

Under such circumstances, materials for forming a protective film using a fluorine-containing resin have been proposed as a means for preventing from both deterioration of the quality of the resist film during liquid immersion lithography by the liquid for liquid immersion lithography and variation of a refractive index associated with deterioration of the liquid itself for liquid immersion lithography (see, for example, Patent Document 1). However, when such a material for forming a protective film is used, though the aforementioned purpose can be attained, problems on the investment efficiency are caused such as those due to the necessity for a special cleaning solution and an applying device for it as well as an increase in the number of processes for removing the protective film.

Furthermore, recently, a process in which an alkali-soluble polymer is used as the protective film on the resist top layer has attracted attention (see, for example, Patent Document 2). However, there have been needs for characteristics enabling to suppress the deterioration of the resist film caused by the liquid for liquid immersion lithography during the liquid immersion lithography and the variation of a refractive index associated with the deterioration of the liquid itself as much as possible. Moreover, in the liquid immersion lithography process, a lens on a tip portion of the lithography device scans the upper surface of the resist covered by a protective film. In other words, the lens of the lithography device, the lens being in contact with the protective film via the interposed liquid for liquid immersion lithography, scans while moving along the planer orientation of the protective film covering the resist. Accordingly, as a surface property of the protective film, a property (scan followability) needs to be provided with which the liquid for liquid immersion lithography, which is displaced along with the lens, is prevented from being withdrawn from the surface. When this scan followability is insufficient, the liquid immersion lithography with high resolution will not be realized.

Non Patent Document 1: Journal of Vacuum Science & Technology B (J. Vac. Sci. Technol. B) (Issued in U.S.A.), Vol. 17, No. 6, pages 3306-3309, 1999

Non Patent Document 2: Journal of Vacuum Science & Technology B (J. Vac. Sci. Technol. B) (Issued in U.S.A.), Vol. 19, No. 6, pages 2353-2356, 2001

Non Patent Document 3: Proceedings of SPIE (Issued in U.S.A.), Vol. 4691, pages 459-465, 2002

Patent Document 1: WO 2004/074937

Patent Document 2: Japanese Unexamined Patent Publication No. 2005-157259

### DISCLOSURE OF THE INVENTION

### Problems to be Solved by the Invention

The present invention has been made in view of the abovementioned problems of conventional art. Specifically, an object of the present invention is to enable to prevent the deterioration of the resist film and the immersion liquid itself during the liquid immersion lithography simultaneously and to form a resist pattern with high-resolution capacity in use of liquid immersion lithography by forming a specific protective film on the surface of the conventional resist film.

### Means for Solving the Problems

To achieve the abovementioned objects, the material for forming a resist protective film according to the present invention is a material, which is used for forming a protective film laminated on a photoresist film on a substrate, the material including an alkali-soluble polymer having a constitutional unit represented by the following general formula (I):

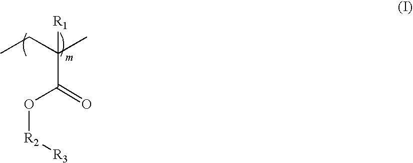

in the formula (I), R₁ represents a hydrogen atom or a methyl group; R₂ represents an alkylene chain having 1 to 5 carbon atoms; R₃ represents a fluorinated alkylene chain having 1 to 10 carbon atoms in which a portion or all of hydrogen atoms thereof are substituted with a fluorine atom; and m represents the number of repeating units.

Furthermore, a method for forming a resist pattern according to the present invention is a method for forming a photoresist pattern by using a liquid immersion lithography process, the method including a photoresist-forming step of forming a photoresist film on a substrate; a protective-film forming step of forming a protective film on the photoresist film by using the material for forming a photoresist protective film; an exposing step of selectively exposing the photoresist film through a liquid for liquid immersion lithography and the protective film after the liquid for the liquid immersion lithography is placed at least on the protective film of the substrate; and a developing step of developing the protective film and the photoresist film by using an alkaline developing solution after the photoresist film is subjected to a heat treatment if necessary, thereby obtaining a photoresist pattern simultaneously with removing the protective film.

### EFFECTS OF THE INVENTION

The material for forming a protective film according to the present invention can be directly used to form a protective film on a resist film and is less likely to inhibit pattern exposure. In addition, the material for forming a protective film of the present invention is water-insoluble and therefore makes it possible to actually use “water (pure water or deionized water) which is a most likely candidate for the liquid for liquid immersion used in liquid immersion lithography satisfying the optical requirements of liquid immersion lithography, being easy to handle, and being free from environmental pollution” as a liquid for immersion lithography. In other words, even when water, which is easy to handle, has an excellent optical properties such as a refractive index and is free from environmental pollution, is used as an immersion liquid for liquid immersion lithography, the material of the present invention sufficiently protects resist films of various compositions during the liquid immersion lithography process so that the resist patterns having excellent properties can be obtained.

In addition, when the exposure light with a wavelength of 157 nm is used as the liquid for liquid immersion lithography, a fluorine-containing medium is a likely candidate for the liquid for liquid immersion lithography from the viewpoint of the exposure light absorption. Even when such a fluorine-containing solvent is used, as in the case of the water mentioned above, it sufficiently protects the resist film during liquid immersion lithography process so that the resist pattern with excellent properties can be obtained. Moreover, since the protective film formed of the material for forming a protective film of the present invention achieves favorable scan followability, it is possible to perform liquid immersion lithography with high accuracy while suppressing the risk of defect occurrences due to remaining micro water droplets, wherever possible.

Furthermore, since the material for forming a protective film of the present invention is soluble in alkaline (developing solution), it is not necessary to remove the formed protective film from the resist film before a development treatment even when the development treatment is to be conducted after the completion of the exposure. Namely, since the protective film obtained by using the material for forming a protective film of the present invention is soluble in an alkaline (developing solution), it is not necessary to provide a protective-film removing step before the developing step after exposure, and the development treatment of the resist film with an alkaline developing solution can be conducted without removing the protective film, thereby making it possible to simultaneously conduct the removal of the protective film and the development of the resist film. Therefore, the method for forming the pattern using the material according to the present invention can efficiently perform the formation of the resist film with an excellent pattern property, while keeping the environmental pollution risk extremely low and reducing the number of processes.

Particularly, since the alkali-soluble polymer used as the material for forming a protective film of the present invention is soluble in various kinds of alcohol, it is possible to provide a material for forming a protective film with favorable coating properties. Moreover, the protective film formed by using the material for forming a protective film of the present invention is insoluble in water and soluble in a developing solution, and achieves favorable scan followability, whereby the risk of defect occurrences due to remaining micro water droplets, can be suppressed wherever possible. Therefore, the shape of the resist pattern does not substantially change even when the protective film is used for the liquid immersion lithography process.

### PREFERRED MODE FOR CARRYING OUT THE INVENTION

In the present invention with the above constitution, liquid immersion lithography can be conducted by using, as a liquid for liquid immersion lithography, water constituted substantially with pure water or deionized water, or a fluorine-based inert liquid. As described previously, taking into account the cost, the ease of post-treatment and low risk of environmental pollution, water is a more preferable liquid for liquid immersion lithography. When exposure light having a wavelength of 157 nm is used, it is preferable to use a fluorine-based solvent which causes less absorption of exposure light. Furthermore, the protective film formed from the material for forming a resist protective film of the present invention is dense, and therefore can suppress permeation of the liquid for immersion lithography into the resist film, has favorable scan followability, and also can suppress the defect risk, wherever possible.

The resist film, which can be used in the present invention, may be any resist film obtained by using a conventional common resist composition, and is not specifically limited. This is also a primary feature of the present invention.

As described above, the essential characteristic as a protective film of the present invention is that the protective film is substantially insoluble in water and alkali-soluble. Furthermore, the protective film is transparent to exposure light, does not promote mixing with a resist film, exhibits good adhesion to a resist film and good compatibility with a developing solution, and has favorable scan followability when the film is formed. As the material for forming a protective film, the material enabling to form a protective film having these characteristics, a composition is used which is prepared by dissolving an alkali-soluble polymer having a constitutional unit represented by the above general formula (I) in a solvent to be described later.

In the general formula (I), it is preferred that R₂ be an alkylene chain having 1 to 3 carbon atoms, and that R₃ be a fluorinated alkylene chain having 3 to 7 carbon atoms in which a portion or all of hydrogen atoms thereof are substituted with a fluorine atom.

More specifically, as the constitutional unit represented by the above general formula (I), it is preferable that at least one selected from the following general formula (II):

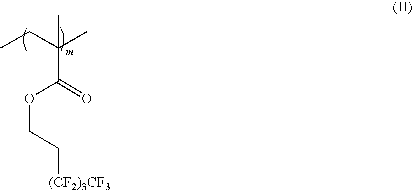

and the following general formula (III):

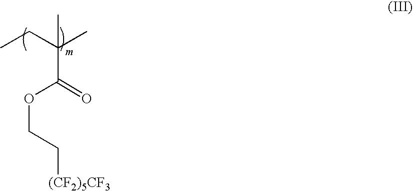

in the formulae (II) and (III), m represents the number of repeating units, be used.

Furthermore, the alkali-soluble polymer may contain a constitutional unit having cyclic hydrocarbon which is substituted with at least one substituent selected from a hydroxyl group, a fluorine atom, a fluoroalkyl group and a fluorinated hydroxyalkyl group.

As the constitutional unit having cyclic hydrocarbon, a constitutional unit represented by the following general formula (IV).

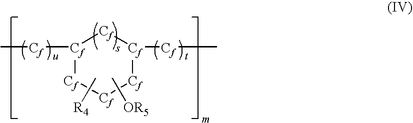

in the formula (IV), C_{f} represents —CH₂—, in which a portion or all of hydrogen atoms thereof may be substituted with a fluorine atom; R₄ represents a linear, branched or cyclic fluoroalkyl group having 1 to 5 carbon atoms, in which a portion or all of hydrogen atoms thereof are substituted with a fluorine atom; R₅ represents a hydrogen atom, or a linear, branched or cyclic fluoroalkyl group having 1 to 5 carbon atoms, in which a portion or all of hydrogen atoms thereof are substituted with a fluorine atom; s, t and u each independently represent an integer of 0 to 3; and m represents the number of repeating units, can be used.

Specifically, examples of the constitutional unit represented by the above general formula (IV) include a constitutional unit represented by the following chemical formula (V):

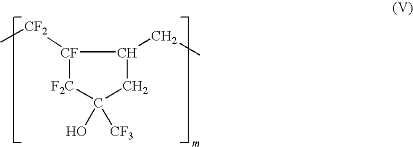

in the chemical formula (V), m represents the number of repeating units.

Moreover, as the constitutional unit having cyclic hydrocarbon, a constitutional unit represented by the following general formula (VI):

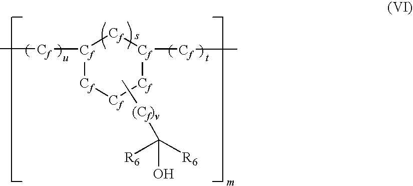

in the formula (VI), C_{f} represents —CH₂—, in which a portion or all of hydrogen atoms thereof may be substituted with a fluorine atom; R₆ represents a linear, branched or cyclic fluoroalkyl group having 1 to 5 carbon atoms, in which a portion or all of hydrogen atoms thereof are substituted with a fluorine atom; R_{f5} represents a hydrogen atom, or a linear, branched or cyclic fluoroalkyl group having 1 to 5 carbon atoms, in which a portion or all of hydrogen atoms thereof are substituted with a fluorine atom; s, t, u and v each independently represent an integer of 0 to 3; and m represents the number of repeating units, can also be used.

Specifically, examples of the constitutional unit represented by the above general formula (VI) preferably include a constitutional unit represented by the following chemical formula (VII):

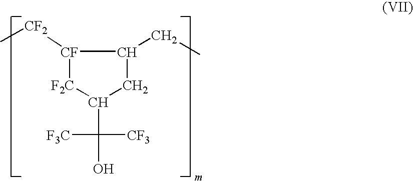

in the formula (VII), m represents the number of repeating units.

A compositional mole ratio of the constitutional unit represented by the above general formula (I) is preferably 70 to 99%, and a compositional mole ratio of the constitutional unit having cyclic hydrocarbon is preferably 1 to 30%.

The constitutional unit represented by the above general formula (I) may be used as a single polymer, may be a copolymer with at least one constitutional unit selected from two constitutional units respectively represented by above the general formulae (IV) and (VI), or may be a mixed polymer with a polymer constituted with at least one constitutional unit selected from two constitutional units respectively represented by the above general formulae (IV) and (VI). Such a constitution makes it possible to improve alkali-solubility and scan followability.

Such a polymer can be synthesized by a known polymerization method. The mass average molecular weight of the resin of these polymer components (based on conversion into polystyrene on GPC) is not particularly limited, but preferably falls within the range of 5,000 to 80,000, and more preferably 8,000 to 50,000.

As the solvent for dissolving the alkali-soluble polymer, any solvent incompatible with a resist film and capable of dissolving the fluoropolymer can be used. As such a solvent, it is possible to use an alcoholic solvent having 1 to 10 carbon atoms, a fluorinated alcoholic solvent having 1 to 10 carbon atoms in which a portion or all of hydrogen atoms thereof are fluorinated, a fluorinated alkyl ether solvent having 4 to 15 carbon atoms in which a portion or all of hydrogen atoms thereof are fluorinated, and a fluorinated alkyl ester solvent having 4 to 15 carbon atoms in which a portion or all of hydrogen atoms thereof are fluorinated. The solvent used in the present invention contains at least one solvent selected from the group of the aforementioned solvents.

The alcoholic solvent is an alcoholic solvent having 1 to 10 carbon atoms, and more specifically, n-butyl alcohol, isobutyl alcohol, n-pentanol, 4-methyl-2-pentanol, and 2-octanol are preferable.

As a solvent to dissolve the alkali-soluble polymer, it is also possible to use a fluorinated alcoholic solvent as described above. Such a fluorinated alcoholic solvent is also incompatible with a resist film and capable of dissolving the alkali-soluble polymer. As the fluorinated alcoholic solvent, the one which contains more fluorine atoms than hydrogen atoms in the molecule is preferable.

It is preferable that the number of carbon atoms in the fluorinated alcohol be from 1 to 10. Specifically, as such alcohol containing fluorine, C₄F₉CH₂CH₂OH and/or C₃F₇CH₂OH can be preferably used.

The fluorinated alkyl ether solvent having 4 to 15 carbon atoms in which a portion or all of hydrogen atoms thereof are fluorinated is ROR′, in which R and R′ each represent an alkyl group; the total number of carbon atoms of the both alkyl groups is 4 to 15; and a portion or all of hydrogen atoms thereof are substituted with a fluorine atom.

Preferable examples of such a fluoroalkyl ether include a compound represented by the following formula (VIII).

HCF₂₂CH₂—OCF₂₂H (VIII)

The fluorinated alkyl ester solvent having 4 to 15 carbon atoms in which a portion or all of hydrogen atoms thereof are fluorinated is RCOOR′, in which R and R′ each represent an alkyl group; the total number of carbon atoms of the both alkyl groups is 4 to 15; and a portion or all of hydrogen atoms thereof are substituted with a fluorine atom.

Preferable examples of such a fluoroalkyl ester include compounds represented by the following formulae (IX) and (X).

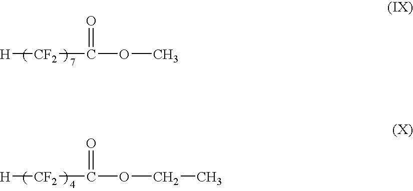

In addition, the material for forming a protective film of the present invention can be combined with an acidic substance. As the acidic substance, a fluorocarbon compound is preferably used. By adding a fluorocarbon compound to the material for forming a protective film of the present invention, the effect of improving the shape of the resist pattern is achieved.

Such fluorocarbon compounds shown below are not the subject to the Significant New Use Rule (SNUR) and thus are usable.

Preferable compounds as such fluorocarbon compounds are a fluorocarbon compound represented by the following general formula (201):

(CₙF₂ₙ₊₁SO₂)₂NH (201)

in which n represents an integer of 1 to 5; a fluorocarbon compound represented by the following general formula (202):

CₘF₂ₘ₊₁COOH (202)

in which m represents an integer of 10 to 15; a fluorocarbon compound represented by the following general formula (203):

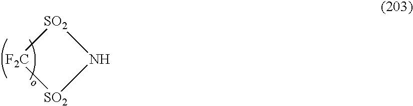

in which o represents an integer of 2 to 3; and a fluorocarbon compound represented by the following general formula (204):

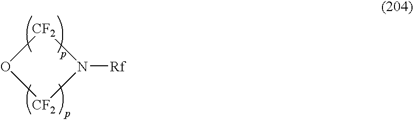

in which p represents an integer of 2 to 3; Rf represents an alkyl group in which a portion or all of hydrogen atoms are substituted with a fluorine atom, and may be substituted with a hydroxyl group, an alkoxy group, a carboxyl group, or an amino group.

Specifically, preferable fluorocarbon compounds as the fluorocarbon compounds represented by the above general formula (201) are a compound represented by the following chemical formula (205):

(C₄F₉SO₂)₂NH (205)

or a fluorocarbon compound represented by the following chemical formula (206):

(C₃F₇SO₂)₂NH (206).

In addition, as the fluorocarbon compound represented by the above general formula (202), specifically, the fluorocarbon compound represented by the formula (207):

C₁₀F₂₁COOH (207)

is preferable.

Specifically, as the fluorocarbon compound represented by the general formula (203), the fluorocarbon compound represented by the following chemical formula (208):

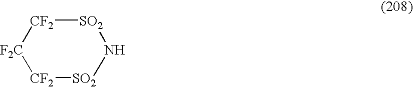

is preferable.

Specifically, as the fluorocarbon compound represented by the above general formula (204), the fluorocarbon compound represented by the following chemical formula (209):

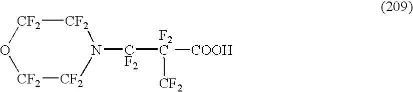

is preferable.

The material for forming a resist protective film of the present invention may be combined with a crosslinking agent including a nitrogen-containing compound having an amino group and/or an imino group, which is substituted with a hydroxyalkyl group and/or an alkoxyalkyl group.

As the nitrogen-containing compound, at least one derivative selected from a melamine derivative, a guanamine derivative, a glycoluril derivative, a succinylamide derivative, and a urea derivative is preferably used.

Specifically, these nitrogen-containing compounds can be obtained, for example, by subjecting the melamine-based compound, urea-based compound, guanamine-based compound, acetoguanamine-based compound, benzoguanamine-based compound, glycoluril-based compound, succinylamide-based compound or ethyleneurea-based compound to a methylolating reaction with formalin in boiling water, and optionally further subjecting the reaction product to a alkoxylating reaction with a lower alcohol such as methanol, ethanol, n-propanol, isopropanol, n-butanol, and isobutanol.

As the crosslinking agent, tetrabutoxymethylated glycoluril is more preferably used.

Furthermore, as the crosslinking agent, a condensation reaction product of a monohydroxymonocarboxylic acid compound, and a hydrocarbon compound substituted with at least one group selected from a hydroxyl group and an alkyloxy group can also be preferably used.

The monohydroxymonocarboxylic acid is preferably monohydroxymonocarboxylic acid in which a hydroxyl group and a carboxyl group are respectively bonded to the same carbon atom, or adjacent two carbon atoms.

A resist pattern forming method for liquid immersion lithography using the protective film of the present invention will now be described.

First, a common resist composition is coated onto a substrate such as silicone wafer with a spinner or the like and then prebaked (PAB treatment). An organic or inorganic antireflective film can be provided between a substrate and a coating layer of a resist composition, to form a two-layered laminate.

The above processes can be conducted by a known method. It is preferable that the operation conditions and the like are appropriately set according to the composition and characteristics of the resist composition used.

Next, on the surface of the resist film (monolayered or multilayered) which has been cured as described above, a composition, which is prepared by dissolving an alkali-soluble polymer having each of the constitutional units represented by the chemical formulae (I) and (IV) in isobutyl alcohol, is uniformly coated and cured, thereby forming a resist protective film.

On the substrate on which the resist film covered with the protective film has been formed, the liquid for liquid immersion lithography (a liquid having a refractive index that is larger than that of air and smaller than that of the resist film, i.e., pure water, deionized water, or fluorine-based solvent in the case specialized in the present invention) is placed.

The resist film on the substrate in this state is selectively exposed through a desired mask pattern. At this time, exposure light penetrates through the liquid for liquid immersion lithography and protective film, reaching the resist film.

At this time, the protective film completely blocks the resist film from the liquid for liquid immersion lithography such as pure water, and thus it effectively controls the deterioration such as swelling caused by the permeation of the liquid for liquid immersion lithography and the deterioration of optical properties such as the refractive index of the liquid for liquid immersion lithography caused by the elution of components into the liquid for liquid immersion lithography such as pure water, deionized water, or a fluorine-based solvent.

The wavelength of light used in the exposure is not specifically limited, and the exposure can be conducted by using radiation such as an ArF excimer laser, KrF excimer laser, F₂ excimer laser, EUV (extreme ultraviolet ray), VUV (vacuum ultraviolet ray), electron beam, X-ray, and soft X-ray. The wavelength of light used in the exposure is mainly decided according to characteristics of a resist film.

As described above, in the method for forming a photoresist pattern of the present invention, a liquid for liquid immersion lithography having a refractive index larger than that of air and smaller than that of the resist film employed is disposed onto the resist film via a protective film upon exposure. Examples of such a liquid include water (pure water, deionized water), or a fluorine-based inert liquid. Specific examples of the fluorine-based inert liquid include liquids containing a fluorine-based compound such as C₃HCl₂F₅, C₄F₉OCH₃, C₄F₉OC₂H₅ or C₅H₃F₇ as a main component. Among these liquids, in view of cost, safety, environmental problems, and general versatility, the use of water (pure water or deionized water) is preferable. When using exposure light having a wavelength of 157 nm, a fluorine-based solvent is preferably used in view of less absorption of exposure light.

The refractive index of the liquid used is not specifically limited as long as it is within range “which is larger than the refractive index of an air and smaller than that of a resist composition used”.

After the exposing step in the liquid immersion state is completed, the liquid for liquid immersion lithography is removed from the substrate.

Next, the resist film is subjected to PEB (post exposure baking), followed by a development treatment using an alkaline developing solution including an aqueous alkaline solution. Since the developing solution used in this development process is alkaline, the protective film is dissolved away simultaneously with the soluble portion of the resist film. The development treatment may be followed by postbaking.

Subsequently, the resist film is rinsed by using pure water or the like. In the water rinsing process, for example, water is dripped or sprayed over the surface of the substrate while rotating, thereby washing away the protective film component and the resist composition dissolved by the developing solution, and the developing solution on the substrate. Then, a resist pattern, in which a resist film is patterned in a shape corresponding to a mask pattern, is obtained by drying.

As described above, in the present invention, removal of the protective film and the development of the resist film are simultaneously achieved by the development treatment. Because the protective film formed by the material for forming a protective film of the present invention has improved water-shedding property, the liquid for liquid immersion lithography can be easily separated after the exposure is completed. Accordingly, the amount of the adhered liquid for liquid immersion lithography is reduced, and so-called leakage of the liquid for liquid immersion lithography is prevented. The protective film formed by the material for forming a protective film of the present invention has improved scan followability in addition to this improved water-shedding property. This is a primary feature of the material for forming a protective film of the present invention.

By forming resist patterns in this way, resist patterns having fine line widths, particularly line-and-space patterns having a small pitch can be produced with good resolution. Here, the term “pitch” in line-and-space patterns refers to a total distance of a resist pattern width and a space width in the line width direction of pattern.

### EXAMPLES

Hereinafter, examples of the present invention will be described. However, these examples are only provided for appropriately illustrating the present invention and do not intend to restrict the present invention at all.

### Example 1

In this Example, four evaluations were performed as basic property evaluation for the material for forming a protective film of the present invention with regards to (1) whether or not the material is soluble in an alcoholic solvent; (2) whether or not the material solution for forming a resist protective film can be uniformly coated on a substrate after, dissolving in an alkaline solvent; (3) whether or not the obtained protective film has resistance to pure water; and (4) whether or not the obtained protective film has solubility in the developing solution.

Regarding the evaluation (1), after placing the following two kinds of materials for forming a protective film in isobutanol, the mixture was observed whether or not the materials were soluble.

As the materials for forming a protective film, two kinds of copolymers respectively represented by the following chemical formulae (XI) and (XII) were used. In the formulae, m and n represent the number of repeating units of the respective monomer units. A copolymer in which m:n=94.7:5.3 (mol %) was used as sample 1 of the chemical formula (XI); and a copolymer in which m:n=90.9:9.1 (mol %) was used as sample 2 of the chemical formula (XII).

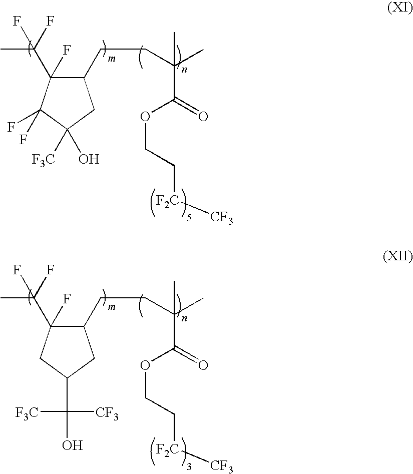

Regarding the evaluation (2), 2.8% by mass of isobutanol solution of each of the materials for forming a protective film was spin-coated on a substrate at 1200 rpm. The obtained coating film was heated and cured at 90° C. for 60 seconds, and the surface state of the cured film (protective film) was visually observed.

Regarding the evaluation (3), pure water was poured onto the cured film (protective film) for 120 seconds, and the film loss (change in the film thickness) before and after that was compared.

Regarding the evaluation (4), the cured film (protective film) was washed with an alkaline developing solution (2.38% aqueous solution of tetramethylammonium hydroxide), and the dissolution rate (in terms of film thickness: nm/second) was calculated. The dissolution rate in this developing solution was measured with Resist Dissolution Analyzer (RDA: manufactured by Litho Tech Japan Co., Ltd.).

The evaluation results are shown in Table 1 below. Referring to Table 1, the following basic properties of the material for forming a protective film of the present invention are confirmed: (1) the material is soluble in an alcoholic solvent; (2) the material solution for forming a protective film dissolved in a alkaline solvent can be uniformly coated on a substrate; (3) the obtained protective film is resistive to pure water; and (4) the obtained protective film has sufficient solubility in a developing solution.

More specifically, the copolymers represented by the chemical formulae (XI) and (XII) are easily dissolved in isobutanol in a concentration of 4.0% by mass. Moreover, each 4.0% by mass of the resin solutions of samples 1 and 2 can be applied with a uniform film thickness without spots by spin-coating. Furthermore, the cured films (protective films) obtained from this uniform coating film were also uniform, and the film thicknesses of the cured films of samples 1 and 2 were respectively 151.0 nm and 136.0 nm. The film thicknesses of these cured films (protective films) after pouring pure water for 120 seconds were 151.3 nm in sample 1 and 136.0 nm in sample 2. It is determined to be in a state where there is no film loss. Furthermore, the dissolution rate of each of the protective films in the alkaline developing solution was 60 nm/sec for sample 1 and 200 nm/sec for sample 2, therefore the developing solution solubility sufficient for development was suggested.

TABLE 1

| | EVALUATION | EVALUATION | EVALUATION | EVALUATION |
|---|---|---|---|---|
| | (1) | (2) | (3) | (4) |
| SAMPLE 1 | SOLUBLE | UNIFORM | 151.0 nm → | 60 nm/sec |
| | | FILM | 151.3 nm | |
| | | THICKNESS | | |
| SAMPLE 2 | SOLUBLE | UNIFORM | 136.0 nm → | 200 nm/sec |
| | | FILM | 136.0 nm | |
| | | THICKNESS | | |

### Example 2

An organic antireflective film composition, “ARC-29A” (trade name, manufactured by Brewer Science Inc.) was coated on a silicone wafer by using a spinner and then dried by baking on a hot plate at 225° C. for 60 seconds to form an organic antireflective film having a thickness of 77 nm. Subsequently, a positive type resist “TArF-P6111ME” (manufactured by Tokyo Ohka Kogyo Co., Ltd) was applied on this antireflective film by a spinner, pre-baked on a hot plate at 130° C. for 90 seconds, and then dried. Consequently, a resist film having a film thickness of 225 nm was formed on the antireflective film.

The copolymers represented by the chemical formulae (XI) and (XII) (samples 1 and 2), respectively, were dissolved in isobutanol to give the material for a protective film, in which the resin concentration was 4.0% by mass. The materials were spin-coated on the resist film, and then heated at 90° C. for 60 seconds to form two kinds of protective films (protective films A and B) having a film thickness of 70.0 nm.

Next, patterning light was irradiated (exposed) through a mask pattern by an lithography device NSR-S302A (manufactured by Nikon Corp., NA (numerical aperture)=0.60, s=⅔ orbicular zone) using ArF Excimer laser (wavelength=193 nm). After the exposing treatment, pure water was continuously dripped onto the protective film at 23° C. for 2 minutes while rotating the substrate, thereby establishing a pseudo-liquid immersion environment.

After the process of dropping pure water, a PEB treatment was conducted at 130° C. for 90 seconds, followed by development with the alkaline developing solution at 23° C. for 60 seconds, leaving the respective protective films as they were. As the alkaline developing solution, a 2.38% by mass aqueous tetramethylammonium hydroxide (TMAH) solution was used. Each protective film was completely removed by this developing step, and the development of the resist film was also satisfactorily achieved.

The resulting resist pattern with a 1:1 line-and-space of 130 nm was observed with a scanning electron microscope (SEM). Any of the pattern profiles was excellent and no fluctuation or the like was observed at all.

### Example 3

Similarly to Example 2, an organic antireflective film composition, “ARC-29A” (trade name, manufactured by Brewer Science Inc.) was coated on a silicone wafer by using a spinner and then dried by baking on a hot plate at 225° C. for 60 seconds to form an organic antireflective film having a thickness of 77 nm. Subsequently, a positive type resist “TArF-P6111ME” (manufactured by Tokyo Ohka Kogyo Co., Ltd) was applied on this antireflective film by a spinner, pre-baked on a hot plate at 130° C. for 90 seconds, and then dried. Consequently, a resist film having a film thickness of 150 nm was formed on the antireflective film.

The copolymers represented by the chemical formulae (XI) and (XII) (samples 1 and 2), respectively, were dissolved in isobutanol to give two kinds of materials for a protective film, in which the resin concentration was 4.0% by mass. The materials were spin-coated on the resist film, respectively, and then heated at 90° C. for 60 seconds to form two kinds of protective films (protective films A and B) having a film thickness of 140.0 nm.

Using a testing device LEIES193-1 (manufactured by Nikon Corporation) for liquid immersion lithography, a two-beam interference test was conducted regarding liquid immersion lithography. Subsequently, a PEB treatment was conducted at 115° C. for 90 seconds, and a development treatment was conducted at 23° C. for 60 seconds by using a 2.38% by mass aqueous TMAH solution. Each protective film was completely removed in this developing step, and the development of the photoresist film was also satisfactorily achieved.

The resulting resist pattern with a 1:1 line-and-space of 65 nm was observed with a scanning electron microscope (SEM). It was found that a line-and-space pattern with an excellent shape was formed.

### Comparative Example 1

By using the positive photoresist similar to that of Example 2, a resist pattern (1:1 line-and-space of 130 nm) was formed in a similar manner to Example 2 except that no protective film was formed, and then observed with a scanning electron microscope (SEM). The fluctuation, expansion or the like of the pattern was observed, and the pattern profile was not excellent.

### Example 4

The cured films (protecting films) of the 150 nm thickness were formed on a substrate by using sample 1 and sample 2 in the aforementioned Example 1. Pure water was dripped as a liquid for liquid immersion lithography onto the respective obtained protective films, and an eye lens of the lithography device was brought into contact with the droplet. As this lithography device, a testing device LEIES193-1 (manufactured by Nikon Corporation) for liquid immersion lithography was used. In this state, the eye lens was scanned horizontally with respect to the protective films. Scan speed was gradually increased, and the scan speed at the time when the droplet got away from the protective film was recorded as a scan resistance value.

Results of the measurement revealed 330 mm/sec in the protective film of sample 1 and 350 mm/sec in the protective film of sample 2. Thus, it was confirmed that the protective film of sample 1 and the protective film of sample 2 both had sufficient scan followability in terms of production efficiency.

### INDUSTRIAL APPLICABILITY

As described above, according to the present invention, it is possible to obtain a highly accurate resist pattern having high sensitivity and superior resist pattern profile, with excellent focal depth, exposure latitude, and post exposure delay stability, even if a resist film is formed by using any conventional resist composition, or any type of liquid for liquid immersion lithography, particularly water or a fluorine-based medium is used in a liquid immersion lithography process. In addition, a dense film can be attained; the deterioration of the resist film and the liquid for liquid immersion lithography employed can be prevented simultaneously during liquid immersion lithography using various liquids for liquid immersion lithography including water; and resistance to post exposure delay of the resist film can be improved without increasing the number of processes. Moreover, according to the material for forming a protective film of the present invention, it is possible to form a protective film with favorable scan followability. Consequently, by using the material for forming a protective film of the present invention, a resist pattern can be effectively formed by using a liquid immersion lithography process.

1. A material for forming a protective film laminated on a photoresist film on a substrate, the material comprising an alkali-soluble polymer having a constitutional unit represented by the following general formula (I): 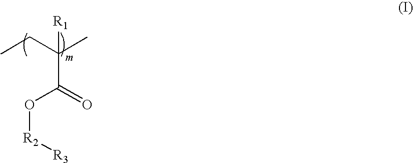
wherein R₁ represents a hydrogen atom or a methyl group;
R₂ represents an alkylene chain having 1 to 5 carbon atoms;
R₃ represents a fluorinated alkylene chain having 1 to 10 carbon atoms in which a portion or all of hydrogen atoms thereof are substituted with a fluorine atom; and
m represents the number of repeating units.

2. The material for forming a protective film according to claim 1,
wherein, in the above general formula (I),
R₂ is an alkylene chain having 1 to 3 carbon atoms, and
R₃ is a fluorinated alkylene chain having 3 to 7 carbon atoms in which a portion or all of hydrogen atoms thereof are substituted with a fluorine atom.

3. The material for forming a protective film according to claim 1,
wherein the constitutional unit represented by the above general formula (I) is at least one selected from the following general formula (II): 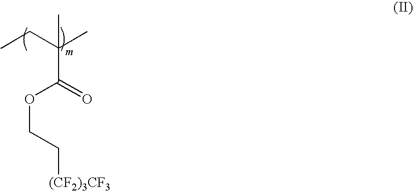
and the following general formula (III): 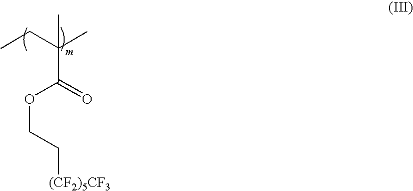
wherein m represents the number of repeating units.

4. The material for forming a protective film according to claim 1,
wherein the alkali-soluble polymer comprises a constitutional unit having cyclic hydrocarbon which is substituted with at least one substituent selected from a hydroxyl group, a fluorine atom, a fluoroalkyl group and a fluorinated hydroxyalkyl group.

5. The material for forming a protective film according to claim 1,
wherein the constitutional unit having cyclic hydrocarbon is a constitutional unit represented by the following general formula (IV): 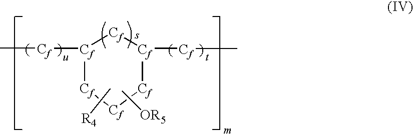
wherein, C_{f} represents —CH₂—, in which a portion or all of hydrogen atoms thereof may be substituted with a fluorine atom;
R₄ represents a linear, branched or cyclic fluoroalkyl group having 1 to 5 carbon atoms, in which a portion or all of hydrogen atoms thereof are substituted with a fluorine atom;
R₅ represents a hydrogen atom, or a linear, branched or cyclic fluoroalkyl group having 1 to 5 carbon atoms, in which a portion or all of hydrogen atoms thereof are substituted with a fluorine atom;
s, t and u each represent an integer of 0 to 3; and
m represents the number of repeating units.

6. The material for forming a protective film according to claim 5,
wherein the constitutional unit represented by the above general formula (IV) is a constitutional unit represented by the following general formula (V): 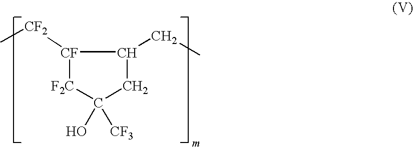
wherein m represents the number of repeating units.

7. The material for forming a protective film according to claim 1,
wherein the constitutional unit having cyclic hydrocarbon is a constitutional unit represented by the following general formula (VI): 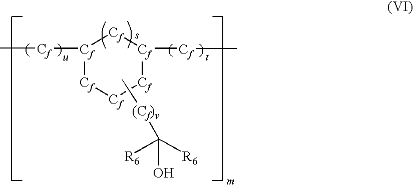
wherein, C_{f} represents —CH₂—, in which a portion or all of hydrogen atoms thereof may be substituted with a fluorine atom;
R₆ represents a linear, branched or cyclic fluoroalkyl group having 1 to 5 carbon atoms, in which a portion or all of hydrogen atoms thereof are substituted with a fluorine atom;
R_{f5} represents a hydrogen atom, or a linear, branched or cyclic fluoroalkyl group having 1 to 5 carbon atoms, in which a portion or all of hydrogen atoms thereof are substituted with a fluorine atom;
s, t, u and v each independently represent an integer of 0 to 3; and
m represents the number of repeating units.

8. The material for forming a protective film according to claim 7,
wherein the constitutional unit represented by the above general formula (VI) is a constitutional unit represented by the following general formula (VII): 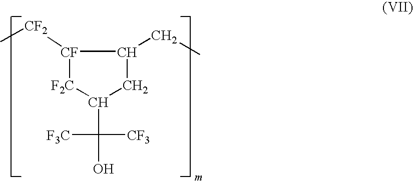
wherein, m represents the number of repeating units.

9. The material for forming a protective film according to claim 1,
wherein a mole ratio of the constitutional unit represented by the above general formula (I) is 70 to 99%, and a mole ratio of the constitutional unit having cyclic hydrocarbon is 1 to 30%.

10. The material for forming a protective film according to claim 1, further comprising
at least one solvent selected from the group consisting of an alcoholic solvent having 1 to 10 carbon atoms,
a fluorinated alcoholic solvent having 1 to 10 carbon atoms in which a portion or all of hydrogen atoms thereof are fluorinated,
a fluorinated alkyl ether solvent having 4 to 15 carbon atoms in which a portion or all of hydrogen atoms thereof are fluorinated, and
a fluorinated alkyl ester solvent having 4 to 15 carbon atoms in which a portion or all of hydrogen atoms thereof are fluorinated.

11. The material for forming a protective film according to claim 1, further comprising an acidic substance.

12. The material for forming a protective film according to claim 11, wherein the acidic substance is a fluorocarbon compound.

13. The material for forming a protective film according to claim 1, further comprising a crosslinking agent.

14. A method for forming a photoresist pattern by using a liquid immersion lithography process, the method comprising:
a photoresist-forming step of forming a photoresist film on a substrate;
a protective-film forming step of forming a protective film on the photoresist film by using the material for forming a protective film according to claim 1;
an exposing step of selectively exposing the photoresist film through a liquid for liquid immersion lithography and the protective film after the liquid for the liquid immersion lithography is placed at least on the protective film of the substrate; and
a developing step of developing the protective film and the photoresist film by using an alkaline developing solution after the photoresist film is subjected to a heat treatment if necessary, thereby obtaining a photoresist pattern simultaneously with removing the protective film.
